(19) United States
(12) Patent Application Publication
(10) Pub. No.: US 2002/0018958 A1
(43) Pub. Date: Feb. 14, 2002

(54) Polymeric material for laser processing and a laminated body for laser processing thereof, flexographic printing plate and the method of producing the same, and a seal material

(75) Inventors: Takashi Nishioka, Tokyo (JP); Katsuo Koshimura, Tokyo (JP); Tadaaki Tanaka, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: JSR CORPORATION, Chuo-ku (JP)

(21) Appl. No.: 09/883,258

(22) Filed: Jun. 19, 2001

(30) Foreign Application Priority Data
Jun. 20, 2000 (JP) 2000-185284
Sep. 29, 2000 (JP) 2000-300272

(51) Int. Cl. G03F 7/34

(52) U.S. Cl. 430/260; 430/258; 430/302

(57) ABSTRACT

The object of the present invention is to provide a polymeric material without odors or fuming and with reduced stickiness of the worked surface of material for seals and workability during laser processing, and the flexographic printing plate and sealing material made of the polymeric material having excellent characteristics of laser processing and having sufficient carving depth. The polymeric material of the present invention is characterized in that the polymeric material is made by crosslinking a polymer composition comprising a polymer which contains an ethylene unit as a repeating unit in content of 45% or more by mass and an organic peroxide.

Another object of the present invention is to provide a laminated body for laser processing with excellent workability upon laser processing and a flexographic printing plate with excellent printing performance and workability and a method for fabricating the same. The laminated body for laser processing of the present invention comprises a polymer layer for laser processing which is fabricated by crosslinking a polymer composition containing an ethylenic copolymer, and a base layer laminated on one of the surfaces of the polymer layer for laser processing, whereby peeling the polymer layer for laser processing from the base layer at the interface.

### BACKGROUND OF THE INVENTION

1. Field of the Invention

The present invention relates to a polymeric material suited specifically for engraving by laser processing and a laminated body for laser processing thereof, flexographic printing plate and the method of producing the same, and a seal material, and more specifically the present invention is related to a polymeric material which is excellent for laser processing without odor emissions and fuming during laser processing and is without surface stickiness, a laminated body for laser processing thereof, flexographic printing plate and the method of producing the same, and a seal material. Further the present invention is concerned with a laminated body for the polymeric material with an excellent performance for laser processing and also flexographic printing plate having an excellent printability and workability, and a method of producing the laminated body and flexographic printing plate. Still further, the present invention is related to a seal material. The polymeric material of the present invention may be used for various purposes of laser processed products such as stamps for electronic devices, industrial rubber products and the like besides flexographic printing plate and a seal material. And the polymeric material provides these products with deeply and precisely engraved patterns or marks. Furthermore, the flexographic printing plate of the present invention is suitable for printing to an object which is large both in thickness and size such as corrugated board and the like, and will be used for printing to merchandise tags, film products and the like as well as when the thickness, hardness and elasticity of the object has been well designed.

2. Description of the Related Art

A printing plate is generally made by forming a convex/concave pattern on the surface of a polymeric material such as vulcanized rubber by carving a sheet of the material into a desired pattern with a carving knife. This method, however, requires a high degree of skill for using handmade engraving and, in addition, there is a limitation for making fine and complex characters or patterns manually. Furthermore, in the conventional production of the flexographic printing plate, it is necessary that each position determined of the hand-made parts are precisely disposed on the polymer sheet such as polyethylene terephthalate film or the like and each parts are adhered to the surface of a sheet with an adhesive agent. It requires time and careful handling.

While the production of the flexographic printing plate is in effect to make a printing plate by crosslinking a phot-sensitive resin by irradiation of ultra violet rays and handling it. But the plate can be easily engraved a fine and a complex character or figure, the photo-lithographic process requires a large amount of organic solvents as a developing medium and this will affect the working environment adversely and cause environmental pollution. In recent years a processing machine with laser beam for producing a printing plate has been developed. In the case of laser processing seal material made of rubber material such as natural rubber, nitrile rubber or the like, unpleasant and strong odors of burnt material are generated and this raises another problem of contamination of the working and neighboring environments. Still further, it was recognized that it is an economically disadvantageous process because of engraving the large plate for many hours when making a large sized plate for a corrugated boad with a side length of 1 m or more.

Moreover, silicone rubber-based material has been developed and has been proven to be a decrease in odors generated during laser processing. There still remain problems such as:

(1) Occasional emission of fuming from the surface of the workpiece during engraving operation.

(2) Inferior repeatability of fine and complex patterns.

(3) Repellency to printing ink due to remaining stickiness on the surface of the plate after laser processing.

And it can't solve the problem being time-consuming and shortening of engraving.

### SUMMARY OF THE INVENTION

The present invention, which solves the problems described above, provides a polymeric material having an excellent workability in laser processing without fuming and without generation of unpleasant odors and, furthermore, with a reduced degree of stickiness on the surface of printing plate materials, and a flexographic printing plate and a sealing product with sufficient carving depth.

Another object of the present invention is to provide a laminated body for laser processing with excellent work performances and a flexographic printing plate with excellent printing capability and workability along with the method for fabricating them.

According to the present invention a polymeric material having the following characteristic features and a laminated body using the polymeric material above, a flexographic printing plate with excellent printing capability and workability along with the method for fabricating them, and a material for seals are provided and consequently the above described problems are solved:

[1] A polymeric material for laser processing being characterized in that a polymer composition comprising a polymer (A) containing 45% or more by mass of an ethylene unit as a repeating unit and an organic peroxide (B) is crosslinked.

[2] A polymeric material for laser processing being characterized in that a polymer composition comprising a polymer (A) containing 45% or more by mass of an ethylene unit as a repeating unit and an organic peroxide (B) and a foaming agent (C) is crosslinked and foamed.

[3] A laminated body for laser processing comprising a polymer layer for laser processing obtained by crosslinking a polymer composition containing an ethylenic copolymer and a base layer laminated to one side of a surface of the polymer layer for laser processing, wherein both layers are capable of being peeled from each other at the interface.

[4] The laminated body for laser processing according to 3 above, wherein the peel strength is in the range of 2 to 40 N/cm when the polymer layer is peeled from the base layer at the interface with a peeling rate of 5 cm/min at 180 degrees.

[5] The laminated body for laser processing according to 4 above, wherein the polymer composition comprises a polymer (A) containing 45% or more by mass of an ethylene unit as a repeating unit and an organic peroxide (B).

[6] The laminated body for laser processing according to 5 above, wherein the base layer is formed using a photopolymerizable composition, wherein a photopolymerizable composition comprising an elastomer and a compound having an ethylenical unsaturated group and a photoinitiator is photocured.

[7] A method for producing a laminated body for laser processing comprising:

a step for forming a polymer sheet by crosslinking a polymerizable composition containing an ethylenic copolymer;

a step for laminating a photopolymerizable layer containing an elastomer and a compound having an ethylenical unsaturated group and a photocuring initiator to the surface of the polymer sheet; and

a step for irradiating ultraviolet ray to one side of the photopolymerizable layer and photocuring the photopolymerizable layer to form a base sheet.

[8] A flexographic printing plate being characterized in that made of a polymeric material for laser processing that a polymer composition comprising a polymer (A) containing 45% or more by mass of an ethylene unit as a repeating unit and an organic peroxide (B) is crosslinked.

[9] A flexographic printing plate being characterized in that made of a polymeric material for laser processing that a polymer composition comprising a polymer (A) containing 45% or more by mass of an ethylene unit as a repeating unit and an organic peroxide (B) and a foaming agent (C) is crosslinked and foamed.

[10] A flexographic printing plate characterized in that a printing pattern is formed by engraving the surface of the polymer layer for laser processing in the laminated body for laser processing comprising a polymer layer for laser processing obtained by crosslinking a polymer composition containing an ethylenic copolymer and a base layer laminated to one side of a surface of the polymer layer for laser processing, wherein both layers are capable of being peeled from each other at the interface, with laser processing.

[11] A flexographic printing plate according to 10 above, wherein the peel strength is in the range of 2 to 40 N/cm when the polymer layer is peeled from the base layer at the interface with a peeling rate of 5 cm/min at 180 degrees.

[12] A flexographic printing plate according to 10 above, wherein a film of polymer resin is laminated on the other surface of the base layer of the laminated body for laser processing.

[13] A method for producing a flexographic printing plate comprising:

a step for making a printing pattern by engraving the surface of the polymer layer for laser processing in the laminated body for laser processing comprising a polymer layer for laser processing obtained by crosslinking a polymer composition containing an ethylenic copolymer and a base layer laminated to one side of a surface of the polymer layer for laser processing, wherein both layers are capable of being peeled from each other at the interface;

a step for cutting the polymer layer for laser processing along the printing pattern; and

a step for peeling a region which the printing pattern of the polymer layer for laser processing has not been formed from the base layer.

[14] A material for a seal characterized in that is made of a polymeric material for laser processing that a polymer composition comprising a polymer (A) containing 45% or more by mass of an ethylene unit as a repeating unit and an organic peroxide (B) is crosslinked.

[15] A material for a seal characterized in that is made of a polymeric material for laser processing that a polymer composition comprising a polymer (A) containing 45% or more by mass of an ethylene unit as a repeating unit and an organic peroxide (B) and a foaming agent (C) are crosslinked and foamed.

Use of a polymeric material for laser processing of the present invention, wherein the polymeric material for laser processing can be obtained preventing emission of unpleasant odors or fuming and occurrence of stickiness of the working surface. In addition, the polymeric material allows for providing a printing plate with sufficient carving depth with ease.

The laminated body comprises a crosslinked polymer layer for laser processing and a base layer and is capable of peeled them off at the interface. The laminated body also attains a sufficient carving depth by laser engraving of printing patterns for flexographic printing. The laminated body shows an excellent workability eliminating emission of fuming, unpleasant odors and stickiness of working surfaces. Moreover, the method for fabricating the laminated body for laser processing comprises the steps for producing a polymer layer for laser processing and a photopolymerizable layer as a base layer followed by photo-polymerization or photocuring. This combination of simple processes achieves continuous fabrication of the laminated body for laser processing with dimensions corresponding to the objectives and uses of the product laminated body continuously.

The flexographic printing plate of the present invention has a flexible laminated body structure. Consequently shows an excellent performance on printing operations with good workability. Furthermore, the flexographic printing plate is made, according to the method for the present invention, followed by removing unengraved regions, whereby laser engraving can be carried out only in the regions where character patterns are present since the polymer layer for laser processing is able to peel at the interface from the base layer. This will considerably reduce processing time and, as a whole, the flexographic printing plate can be made within a short period of time.

### DETAILED DESCRIPTION OF THE INVENTION

The polymeric material for laser processing of the present invention comprises a crosslinked polymer composition containing a polymer (A) having 45% or more by mass of an ethylene unit as a repeating unit and an organic peroxide (B).

Another polymeric material for laser processing of the present invention comprises a crosslinked and foamed polymer composition containing a polymer (A) having 45% or more by mass of an ethylene unit as a repeating unit and an organic peroxide (B) and a foaming agent (C).

The polymer (A) described above contains an ethylene unit having 45% or more by mass as a repeating unit [hereinafter referred to as polymer (A)] is not limited, however, 45 to 97% by mass is preferable, and 47 to 80% by mass is more preferable, and still further 50 to 70% by mass is the most preferable content of an ethylene unit. In the above-mentioned range, the polymer (A) can be used as a material for a sufficiently flexible printing plate and the like during laser processing without emission of unpleasant odors. When the ethylene unit content is less than 45% by mass, emission of unpleasant odors increases and further, mechanical strength of the polymeric material decreases. On the other hand, when the ethylene unit content exceeds 97% by mass, then stiffness of the printing plate that has been made of the material becomes excessively high and may fail to provide clear printing on corrugated board surfaces due to the lack of flexibility and allows the surface of the printing plate to possibly deform the corrugated board surfaces.

In the polymer (A), other repeating unit than ethylene is not specified, an α-olefine, a non-conjugated polyene and the like can be used.

As the α-olefin described above there may be mentioned propylene, 1-butene, 1-hexene, 4-methyl-1-pentene, 1-heptene, 5-methyl-1-hexene, 1-octene, 5-ethyl-1-hexene, 1-nonnene, 1-decene and the like. Among these listed above, propylene, 1-butene and 1-octene are preferable. It should be noted that the α-olefin with 4 or more carbon atoms provide flexible and easily deformable printing plate or the like will be obtained. These α-olefins may be used alone or in combination of two or more.

As the non-conjugated polyene described above there may be mentioned:

(1) cyclic polyene such as 5-ethyliden-2-norbornene, dicyclopentadiene, 5-propyriden-2-norbornene, 5-vinyl-2-norbornene, 2,5-norbornadiene, 1,4-cyclohexadiene, 1,4-cyclooctadiene and the like,

(2) chain polyene such as 1,4-hexadiene, 1,5-heptadiene, 1,6-octadiene, 1,7-nonadiene, 1,8-decadiene and the like. Among listed above 5-ethyliden-2-norbornene, dicyclopentadiene, and 1,4-hexadiene are preferable. These non-conjugated polyenes may be used alone or in combination of two or more.

As the polymer (A) having both ethylene unit and α-olefin unit as repeating unit, ethylene/propylene rubber, ethylene/butene rubber and the like may be used. Further, as the polymer (A) having an ethylene unit, an α-olefin unit and a non-conjugated polyene unit as a repeating unit, ethylene/propylene/5-ethyliden-2-norbornene rubber, ethylene/butene/dicyclopentadiene rubber may be used. These rubbers generally contain 50 to 70% by mass of an ethylene unit and can be used for a laser processing product with excellent characteristics for laser processing.

The polymer (A) may contain a repeating unit consisting of other monomers than mentioned above. These include vinyl acetate, vinyl alcohol, styrene, (meth)acryronitrile, (meth)acrylic acid and its metal salt, (meth)acrylate. These monomers can be used alone or in combination of two or more. Additionally, the monomer described above may be used together with at least one of the α-olefins and the non-conjugated polyenes, and the polymer (A) can be a polymer formed by ethylene and a monomer that is copolymerizable with ethylene.

The polymer (A) can be a polymer that a group or a unit of acid anhydride incorporated in the structure of the polymer (A). The acid anhydride can be incorporated into the molecular chain of the polymer (A) by copolymerization of ethylene with a monomer having both a polymerizable unsaturated group and an acid anhydride group such as maleic anhydride, phthalic anhydride, succinic anhydride or the like, and with additional other monomer if necessary, into the molecular structure of the resulting copolymer. More specifically, an acid anhydride unit can be incorporated by copolymerization of an acid anhydride having a polymerizable unsaturated group, such as maleic anhydride, phthalic anhydride, succinic anhydride and the like, with other monomer including ethylene. Alternatively, an acid anhydride group can be incorporated within a resulting molecular structure by graft polymerization of the acid anhydride described above to a polymer having a unit of ethylene.

The polymer (A) can be blended with other polymer if necessary, and a polymer such as natural rubber, butadiene rubber, styrene/butadiene rubber, isoprene rubber, nitrile rubber, acrylic rubber, polyvinylchloride resin, butyl rubber, fluorine rubber, silicone rubber, urethane rubber, polyvinylalcohol or the like. These polymers are used alone or in combination of two ore more.

Further, the amount of these polymers to be incorporated ranges preferably from 5 to 50 parts by mass, more preferably 10 to 40 parts by mass and most preferably 15 to 30 parts by mass, based on 100 parts by mass of the polymer (A) (hereinafter abbreviated to as a “part”).

If the amount of the blended polymer exceeds 50 parts by mass, emission of unpleasant odors increase during laser processing. Further, when the ethylene unit content in the polymer (A) is low, then it is preferable to blend other polymer in smaller quantity.

The organic peroxide (B) is a compound expressed as general formula R¹—O—O—R² where R¹ is an alkyl or acyl, R² is an alkyl, acyl, or hydrogen atom. As the organic peroxide (B) there may be mentioned t-butylhydroperoxide, 1,1,3,3-tetramethyl butylhydroperoxide, p-methanhydroperoxide, cumenhydroperoxide, diisopropyl-benzenehydroperoxide, 2,5-dimethylhexane-2,5-dihydroperoxide, 1,1-di-t-butylperoxy-3,3,5-trimethylcyclohexane, di-t-butylperoxide, t-butylcumylperoxide, dicumylperoxide, dicumylperoxide, 1,1-bis(t-butylperoxi)cyclododecane, 2,2-bis(t-butylperoxy)octane, 1,1-di-t-butylperoxicyckohexane, 2,5-dimethy-2,5-di(t-butylperoxy)hexane, 2,5-dimethy-2,5-di(t-butylperoxi)hexine, 1,3bis(t-butylperoxi-i-propyl)benzene, 2,5-dimethyl-2,5-di(benzoylperoxy)hexane, 1,1-bis(t-butylperoxi)-3,3,5-trimethylcyclohexane, n-butyl-4,4-bis(t-butylperoxi)varelate, benzoylperoxide, m-toruyl-peroxide, p-chlorobenzoylperoxide, 2,4-dicyclobenzoylperoxide, t-butylperoxy-i-butylate, t-butylperoxi-2-ethylhexanoate, t-butylperoxibenzoate, t-butylperoxi-i-propylcarbonate,t-butylperoxi-allylcarbonate and the like.

The organic peroxide (B) can be suitably selected for use according to the corresponding working condition, but in general t-butylcumylperoxide, dicumylperoxide, 2,5-dimethyl-2,5-di(t-butylperoxy)hexane, and 1,3-bis(t-butylperoxy-i-propyl)benzene are preferable. These organic peroxides are used alone or in combination of two or more.

The organic peroxide (B) is preferably used in the amount of 0.1 to 30 parts to 100 parts of the polymer (A), and more preferably 0.1 to 15 parts, and further 0.1 to 10 parts. Referring to the above range the polymer (A) will not be crosslinked sufficiently when the amount of organic peroxide (B) used is less than 0.1 parts, and, consequently, mechanical strength of the polymeric material for laser processing tends to decrease. On the other hand, when the amount of organic peroxide is in excess of 30 parts, the polymer (A) is excessively crosslinked and becomes hard and brittle in nature. This is also not preferable since mechanical and thermal stabilities of the polymeric material for laser processing decrease remarkably.

A monomer that is capable of establishing a crosslinked structure between molecules of the polymer (A) can be successfully incorporated together with the organic peroxide (B). As the crosslinkable monomer there may be mentioned ethylene glycol di-methacrylate, polyethyleneglycol di-methacrylate, trimethyrol propane tri-acrylate, allyl methacrylate, triallyl cyanulate, triallyl iso-cyanulate, diallyl phthalate, divinyl adipate, maleic anhydride, N, N-m-phenylene-bis-maleimide, divinylbenzene, diallylmaleimide, diphenylguanizine and the like.

Another type of monomer which will provide a crosslinking between the polymer (A) molecules by metal can also be used. The monomer includes aluminum acrylate, aluminum methacrylate, zinc acrylate, zinc methacrylate, zinc di-metharylate, magnesium acrylate, magnesium methacrylate, calcium acrylate, calcium methacrylate and the like.

Additionally, other ingredients including liquid polybutadiene, liquid styrene/butadiene rubber, dimethyl aniline, and quaternary ammonium salt and the like, can be used in conjunction with the organic peroxide (B).

The polymeric material for the laser processing of the present invention can be fabricated by crosslinking and foaming the polymer composition comprising the polymer (A) described above and the organic peroxide (B) and furthermore, a foaming agent (C). With the foaming process, performed concurrently with crosslinking the polymer composition during the preparation of the printing plates, specifically when scanning rates are increased by the laser beams, a printing plate having a printing pattern with sufficient carving depth can be obtained, and thus the printing plate is manufactured efficiently.

As the foaming agent (C) there may be mentioned:

(1) inorganic foaming agent such as sodium bicarbonate in the form of paste or fine powder, ammonium hydrogencarbonate and the like,

(2) nitroso compound such as N,N′-dinitroso-pentamethylene tetramine and the like,

(3) azo compound such as azodicarbonamide and a complex foaming composition with the acid amide as the primary ingredient, azo-isobutylonitrile and the like,

(4) sulfonyl hydroazide such as benzenesufonylhydoazide, p,p′-oxy-bis(benzene sulfonylhydroazide), toluene sulfonylhydroazide, p-toluene sulfonyl semicarboazide and the like. Among these listed above N, N′-dinitroso-pentamethylene tetramine, azodicarbonamide, p,p′-oxy-bis(benzene sulfonylhydrazide) are preferable. The foaming agent listed above can be used alone or in combination of two or more.

The amount of the foaming agent (C) described above to be incorporated ranges preferably from 0.05 to 20 parts, and more preferable 0.1 to 10 parts, and most preferably 0.5 to 5 parts, based on 100 parts by mass of the polymer (A) . When the amount of the foaming agent (C) is less than 0.05 parts an insufficient foaming will occur. On the other hand, when the amount of the foaming agent (C) exceeds 20 parts will be uneconomical, and moreover, the printing plate using this will not have sufficient pliancy, causing it to be undesirable.

A foaming aid is generally used together with a foaming agent (C). As the foaming aid there may be mentioned salicylic acid, urea, and their derivatives or the like. More practically, “Cellpaste” series (trade name) from Eiwa Kasei Co., Ltd., “BK” (trade name) from Ouchishinko Chemical Industrial Co., Ltd., “Cellton” series (trade name) from Sankyokasei Co., Ltd., and “Aidon” (trade name) from Shiraishi Calcium Co., Ltd., are commercially available and used alone or in combination of two or more.

The amount of the foaming aid is preferably 0.05 to 20 parts and more preferably 0.1 to 10 parts and still more preferably 0.5 to 5 parts, based on 100 parts by mass of the foaming agent (C). When the amount of the foaming aid is less than 0.05 parts, a sufficient foaming effect is not achieved. On the other hand, the amount of the foaming aid exceeding 20 parts is uneconomical and not desirable.

The polymer composition concering the present invention may be formulated with other ingredients such as a reinforcing agent, plasticizer, activation agent, flame retarder, antioxidant, coloring dye and pigment, as required. As reinforcing agent there may be mentioned a carbon black and a white reinforcing agent such as calcium carbonate, a specific complex of calcium carbonate consisting of calcium carbonate and magnesium carbonate, magnesium carbonate, dry silica, wet silica, colloidal silica, clay, talc or the like. These reinforcing agents can be incorporated alone or in combination of two or more.

As the plasticizers there may be used a process oil such as aromatics, naphthenics and paraffinics.

The accelerator may be used zinc oxide which also functions as a vulcanization accelerator and other commonly used accelerators include unique types of zinc oxide which are activated, transparent, surface treated, or of a complex zinc oxide. In addition, other inorganic accelerators can also be used. They include magnesium oxide, red lead, white lead as those of an inorganic, and further, organic accelerators such as fatty acids including stearic acid, oleic acid, laurylic acid or the like, and derivatives of fatty acids including zinc stearate, di-butyl ammonium oleate or the like which can also be used.

The flame retardant may be used antimony oxide, antimony, chlorinated paraffin, bromine, zirconium and phosphate and aluminum hydroxide, magnesium hydroxide, zinc borate or the like can be used frequently.

As an antioxidant, p-phenylenediamine, quinoline, phenol, hindered phenol and the like can be used.

As coloring agent and pigment there may be mentioned titanium oxide, zinc oxide, lithopone, white lead, chrome yellow, cadmium yellow, barium yellow, cadmium red, molybudenumred, red lead, amber, ultramarineblue, iron blue, cobalt blue, chromium oxide green, cobalt purple and the like as inorganic. Benzidine yellow G, brilliantcurmine 6B, permanent F-5R, lake red G, phthalocyanine green, and phthalocyanine blue and the like as organic. These coloring agents and pigments are used alone or in combination of two or more.

The polymer composition concerning the present invention can be prepared using a conventional kneader, an extruder and the like.

Possible steps for preparation of the polymer composition are cited as follows: first, the polymer (A) is admixed with reinforcing agent, plasticizer and accelerator in an bunbury mixer, a kneader or the like and then the organic peroxide (B) and, if necessary a foaming agent (C) and a foaming aid as well, is formulated and blended with the admixture.

The polymer composition thus prepared is subjected to crosslinking or foaming in a case wherein the foaming agent (C) has been incorporated by such a conventional process for producing vulcanized rubber as filling the material into a mold followed by heating and the resulting product material can be adapted to laser processing. Alternatively, the polymer composition is molded into a predetermined structure, and then the formed product is heated and crosslinked or foamed in the case wherein the polymer composition contains the foaming agent (C) concurrently, resulting in the product material being adapted for laser processing.

The laminated body for laser processing of the present invention comprises the polymer layer for laser processing, made by crosslinking the polymer composition containing an ethylenic copolymer and the base layer laminated on one of the surfaces of the polymer layer for laser processing, and the laminated body is characterized in that it is capable of being peeled at the interface between the polymer layer for laser processing and the base layers.

As for the extent of separation of the polymer layer from the base layer it may be sufficient in necessary region for printing, for example, the polymer layer remains positioned on the base layer satisfactorily to carry out printing operations without problems. In practicality, however, the peel strength between the polymer layer for laser processing and the base layers can be set within a range from 2 to 40 N/cm (more preferably from 3 to 20 N/cm and most preferably from 4 to 12 N/cm) when they are peeled with a peeling rate of 5 cm/min and turnover of 180 degrees. When the peel strength is smaller than 2 N/cm the polymer layer for laser processing will be peeled from the base layer during printing operation, and when the peel strength exceeds 40 N/cm, the regions in the polymer layer for laser processing, where no printing pattern is formed will not be easily peeled from the base layer, and this will be undesirable, leaving the possibility of destroying either the polymer layer for laser processing or the base layer by forced separation.

An ethylenic polymer described above is not limited to specific polymer, but the ethylene unit content is preferably 45 to 97% by mass, more preferably 47 to 97% by mass and 50 to 70% by mass of an ethylene unit as a repeating unit is particularly preferable. Those containing an ethylene unit fraction in a polymer described above do not emit unpleasant odors during laser processing and provide a printing plate or the like with sufficient pliancy. When the ethylene unit content is less than 45% by mass, emission of unpleasant odors increases and further, mechanical strength of the polymeric material decreases. On the other hand, when the ethylene unit content exceeds 97% by mass, rigidity of the printing plate made of the polymer is so high that printing, particularly on corrugated board, fails to provide the surface of the corrugated board with clear printing due to the incapability of following deformation of the printing plate surface.

As the ethylenic polymer, the polymer (A) described above can be advantageously used.

Further, the polymer composition concerning the present invention is able to contain the ethylenic polymer described above, an organic peroxide and a foaming agent. The organic peroxide and the foaming agent can be advantageously selected among those cited previously referring to the organic peroxide (B) and the foaming agent (C) respectively. Still further, additives and polymers cited previously can be incorporated as necessary.

The polymer layer for laser processing is prepared by the same process as that of the polymeric material for laser processing. The thickness of the polymer layer for laser processing is preferably 0.5 to 7.0 mm (more preferably 1.0 to 6.0 mm, most preferable thickness is 2.0 to 4.0 mm). When the thickness is less than 0.5 mm the carving depth is insufficient, and consequently a fine pattern cannot be reproduced. On the other hand, when the thickness exceeds 7.0 mm the printing plate will become too heavy to handle and deteriorate in workability. In both cases, undesirable results are obtained.

The constituent of the base layer is not restricted. However, the base layer can be formed by photocuring an elastomer, a compound having an ethylenical unsaturated group and photopolymerizable composition containing a photoinitiator. The elastomer is not limited, and may be mentioned ruber such as natural rubber, butadiene rubber, styrene/butadiene rubber, isoprene rubber, acrylonitorile/butadiene rubber, acryl rubber, butyl rubber, fluorine containing rubber, silicone rubber, urethane rubber or the like, and thermoplastic elastomer or the like. As thermoplastic elastomer there may be mentioned olefin-based, aromatic vinyl-based, diene-based, urethane-based, polyester-based, polyamide-based, vinyl chloride-based, fluorine-based and the like.

As the olefin-based thermoplastic elastomer (hereinafter described as TPO) there may be mentioned simple blend type TPO, in-planted type TPO and dynamic crosslinked type TPO or the like. And as the aromatic vinyl-based thermoplastic elastomer there may be mentioned styrene/butadiene block copolymer, styrene/butadiene/styrene block copolymer, styrene/(styrene-butadiene)/styrene block copolymer, styrene/isoprene/styrene copolymer, styrene/(ethylene-butylene)/styrene block copolymer, styrene/(ethylene-propylene)/styrene block copolymer, a hydrogenated polymer of random styrene/butadiene rubber, block copolymer of the block copolymer described above and the like, in which the contents of styrene are either partially or totally replaced by α-methylene, with aromatic vinyl compounds and conjugated di-olefines.

As the diene-based thermoplastic elastomer there may be mentioned syndiotactic 1,2-polybutadiene, trans-1,4-polyisoprene and the like. As the polyester-based thermoplastic elastomer there may be mentioned multi-block polymer using polybutylene terephthalate as a hard segment and poly-tetramethylene ether glycol as a soft segment or the like. Further, as the polyamide-based thermoplastic elastomer there may be mentioned block polymer using nylone as a hard segment and polyester or polyol as a soft segment or the like.

Among these thermoplastic elastomers listed above, styrene/butadiene/styrene block copolymer, styrene/isoprene/styrene block copolymer, styrene/(ethylene-butylene)/styrene block copolymer, styrene/(ethylene-propylene)/styrene block copolymer, a hydrogenated polymer of random styrene/butadiene rubber are preferably used taking into account characteristics such as material hardness and repellent elastic modulus, and fabrication performance.

The compound having ethylenical unsaturated group is not limited so far as it is compatible with the binder polymer to an extent that a transparent photopolymerizable layer is formed without being cloudy when it is mixed with the elastomer described above. There may be mentioned

(1) Alkyl (metha)acrylate compound such as methyl methacrylate, ethyl (metha)acrylate, n-butyl (metha)acrylate, iso-butyl (metha)acrylate, t-butyl (metha)acrylate, n-hexyl (metha)acrylate, 2-ethylhexyl (metha)acrylate, lauryl (metha)acrylate, di-cyclopentenyl (metha)acrylate and the like,

(2) Ether-based (metha)acrylate compound such as 2-methoxyethyl (metha)acrylate, 2-ethoxyethyl (metha)acrylate, 3-methoxbutyl (metha)acrylate, ethylcarbitol (metha)acrylate, phenoxyethyl (metha)acrylate, methoxy-propylene glycol (metha)acrylate, n-butoxyethyl (metha)acrylate, methoxy-triethylene glycol (metha)acrylate, n-butoxyethyl (metha)acrylate, methoxy-triethylene glycol (metha)acrylate, glycidil (metha)acrylate and the like,

(3) Alcohol-based (metha)acrylate compound such as 2-hydroxyethyl (metha)acrylate, 2-hydroxypropyl (metha)acrylate, 2-hydroxybutyl (metha)acrylate, 4-hydroxybutyl (metha)acrylate, 2-(metha)acryloyloxyethyl-2-hydroxypropyl phthalate, 2-hydroxy-3-phenoxypropyl acrylate and the like,

(4) Carboxtlic acid-based (metha)acrylate compound such as 2-(metha)acryloyloxyethoxy succinic acid, 2-(metha)acryloxyethyl phthalic acid, 2-methacryloyloxyethyl-hexahydro phthalic acid, (ω-carboxy-polycaprolactone mono(metha)acrylate, acrylic acid dimer and the like,

(5) Bifunctional acrylate such as 1,4-butanediol di(metha)acrylate, 1,3-butyleneglycol di(metha)acrylate, 1,6-hexane diol di(metha)acrylate, 1,9-nonandiol di(metha)acrylate, neopentyl glycol di(metha)acrylate, ethylenglycol di(metha)acrylate, triethylene glycol di(metha)acrylate, polyethyleneglycol di(metha)acrylate, tripropylene glycol di(metha)acrylate, polypropylene glycol di(metha)acrylate, tetraethylene glycol di(metha)acrylate, 1,4-cyclohexane dimethanoldi(metha)acrylate, [di(methacrylate) added ethylene oxide] bisphenol A, [di(methacrylate) added ethylene oxide] bisphenol F, and the like,

(6) Multifunctional acrylate such as trimethylol propane tri(metha)acrylate, pentaerythritol tri(metha)acrylate, ethylene oxide transformed trimethylol propane tri(metha)acrylate, propylene oxide transformed trimethylol propane tri(metha)acrylate, pentaerythritol tetra(metha)acrylate, dipentaerythritol hexa(metha)acrylate and the like.

In addition polybutadiene oligomer and urethane acrylate polymer both having ethylenical unsaturated group or the like may be used. It should be mentioned that the compound listed above is generally used in an amount 3 or more parts to 100 parts of the elastomer. When the amount of the compound is less than 3 parts, it becomes difficult to obtain either the mechanical strength or elasticity sufficiently.

As for the photoinitiator, a conventional compound can be successfully used. There may be mentioned benzophenone, Michler's ketone [4,4′-bis(dimethyamino)benzophenone], 4,4′-bis(diethylamino)benzophenone, 4-acryloxy-4′-dimethylaminobenzophenone, 4-acryoxy-4′-diethylaminobenzophenone, 2,2-dimethoxy-1,2-diphenylethane-1-on(2-phenyl-2,2-dimethoxyacetophenone), 2,2-diethoxy-1,2-diphenylethane-1-on, 1-hydroxy-cyclohexyl-phenyl-ketone, 2-hydroxy-2-methyl-1-phenyl-propane-1-on, 1-[4-(2-hydroxyethoxy)-phenyl]-2-hydroxy-2-methyl-1-propane-1-on, 2-methyl-1[4-(methylthio)phenyl]-2-morphorinophenyl)-butanone-1, bis(2,6-dimethoxybenzoyl)-2,4,4-trimethyl-benzyl phosphine oxide and the like.

The photoinitiator described above is used preferably in an amount of 0.1 to 20 parts, more preferably 0.05 to 15 parts and most preferably 0.1 to 10 parts to 100 parts of the elastomer. When the amount is less than 0.01 parts an insufficient curing of the compositions will be resulted. On the other hand, when a larger amount of the initiator exceeding 20 parts is used, it is uneconomical and moreover, the hardness of the resulting material becomes excessively high and this tends to cause brittleness in the material.

If necessary a retarder for thermal addition-polymerization, a colorant, an antioxidant and a plasticizer can be incorporated into the photopolymerizable composition. As the retarder for thermal addition-polymerization there may be mentioned:

(1) Hydroxy aromatic compound such as hydroquinone, alkyl hydroquinone, alkoxy hydroquinone, aryl hydroquinone, p-methoxyphenol, t-butyl pyrocatechol, pyrogallol, β-naphthol, 2,6-di-t-butyl p-cresol and the like,

(2) Quinone such as benzoquinone, 2,5-diphenyl p-benzoquinone, p-toluquinone, p-xyloquinone and the like,

(3) Nitro or nitroso compound such as nitrobenzene, m-dinitrobenzene, 2-methyl-2-nitrosopropane, α-phenyl-t-butylnitron, 5,5-dimethyl-1-pyrolin-1-oxide and the like,

(4) Amine such as chloranyl-amine, diphenylamine, diphenylpicrylhydrazine, phenol-α-naphthylamine, pyridine, phenothiazine and the like,

(5) Sulfide such as dithiobenzoylsulfide, dibenzylsulfide and the like,

(6) Unsaturated compound such as 1,1-diphenyethylene, α-methylthioacrylonitrile and the like.

(7) Thiazine dye such as thionine blue, toluidine blue, methylene blue and the like,

(8) Stabilized radical such as 1, 1-diphenyl-2-picrylhydrazil, 1,3,5-triphenyl feldazine, 4-hydroxy-2,2,6,6-tetramethyl piperidine-1-oxyl, 2,6-di-t-butyl-α-(3,5-di-t-butyl)-4-oxo-2,5-cyclohexadiene-1-iriden-p-trioxyl and the like.

The amount of retarder for thermal addition-polymerization corresponds preferably to 0.01 to 5% by mass of the whole photopolymerizable composition and can be used alone or in combination of two or more.

As the colorant used for the base layer there may be mentioned:

(1) Basic dye such as Victoria Pure Blue, Victoria Blue, Methyl Violet, Eisen Malachite Green (made by Hodogaya Chemical Co. Ltd.), Patent Pure Blue VX, Rhodamine B, Methylene Blue (made by Sumitomo Chemical Co., Ltd.) and the like,

(2) Oil soluble type dye such as Sudan Blue II, Victoria Blue F4R (made by BASF), Oil Blue #603, Oil Blue BOS, Oil blue IIN (made by Orient Chemical Industries, Ltd.) and the like.

As the antioxidant there may be mentioned 2,6-di-t-butyl p-cresol, 2,2-methylene-bis-(4-methyl-6-t-butylphenol), pentaerythrityl-tetrakis[3-(3,5-di-t-butyl-4-hydroxyphenyl) propionate, 2,4-bis[(octylthio)methyl] o-cresol, tris-(3,5-di-t-butyl-4-hydroxybenzyl)-isocyanurate and the like.

As the plasticizer, there may be used:

(1) Process oil such as aromatic process oil, naphthenic process oil, paraffin-based process oil and the like,

(2) Dialkyl phthalate such as dibutyl phthalate, dihexyl phthalate, di-2-ethylhexyl phthalate, diheptyl phthalate, dioctyl phthalate, dinonyl phthalate and the like,

(3) Dialkyl adipate such as di-2-ethylhexyl adipate, dioctyl adipate, di-i-decyl adipate and the like.

The preferable thickness of the base layer ranges from 1.0 to 7.0 mm (more preferably 2.0 to 6.0 mm and still more preferably 3.0 to 5.0 mm). If the thickness of the base layer is less than 1.0 mm a sufficient strength and performance necessary for the base layer is not achieved. A thick base layer having a thickness exceeding 7.0 mm is not desirable due to inferior workability caused by the heavy weight of the plate.

The method for fabricating the laminated body for laser processing of the present invention is characterized by comprising the steps of:

forming a polymer sheet for laser processing by crosslinking a polymer composition including a ethylenic copolymer; and then,

laminating an elastomer, a compound having an ethylenical unsaturated group and a photopolymerizable composition material containing a photoinitiator on the surface of the polymer sheet for laser processing; and, irradiating ultraviolet rays to the photopolymerizable layer side, and photocuring the photopolymerizable layer in order to form the subjected base layer.

The process of forming the polymer sheet for laser processing, wherein preparation of the polymer composition is prepared at first, will now be described. The ingredients excluding organic peroxide, crosslinkable monomer, foaming agent and foaming aid, that is the ethylenic copolymer described above and various kinds of addition agents are premixed and kneaded in a bunbury mixer or a kneader and the like. Then the organic peroxide, the crosslinkable monomer, and the foaming agent and the foaming aid are blended, and if necessary are further admixed.

The polymer composition thus prepared is crosslinked or foamed according to a generally known method for producing vulcanized rubber, for instance, in a mold under heat resulting in a polymer sheet for laser processing. Alternatively, the polymer sheet can be obtained by heating and crosslinking and/or foaming a formed part after the polymer composition has been formed in a predetermined shape by an extrusion molder.

In the process of forming the base sheet described above, the photopolymerizable composition is prepared by homogeneously admixing all ingredients, and the prepared mixture is subjected to lamination on the polymer sheet by an extruder in sheet form, for instance, and then is cured by irradiation of ultraviolet rays resulting in the base sheet. The intensity of the UV irradiation is determined by taking types and fractions of the elastomer, the compound having ethylenical unsaturated group and the photo-polymerization initiator into consideration. In general, the intensity can be designed as 0.5 to 500 W/m² (while it is more preferably 5 to 200 W/m² and still more preferably 10 to 50 W/m²). While the laminated body for laser processing, which the polymer sheet for laser processing adheres adequately to the surface of the base sheet is obtained, irradiation of ultraviolet rays also occurs. The light source of the ultraviolet rays is not limited, when irradiated the ultraviolet rays, either of a metal halide lamp or a high pressure mercury lamp can be advantageously used.

The thickness of the laminated body can be adjusted through compression, extrusion and the like taken, in general, before the irradiation process by ultraviolet rays. When compression is applied, neither pressure nor temperatures are specified. When an extrusion is applied, such conditions as pressure, temperature and transfer rate of a laminated body in sheet form are not confined.

The flexographic printing plate of the present invention is characterized in that the material for the printing plate is made of the above described polymeric material for laser processing. The flexographic printing plate may have another material other than the polymeric material which is laminated on the non-printing surface. Other materials which are preferably flexible include foamed polyurethane and the like. This will reduce both printing pressure and weight of the printing plate concurrently and a light weight printing plate is especially regarded when a relatively large printing plate is used as in the case of printing on the surface of corrugated board.

Another flexographic printing plate of the present invention is characterized in that the surface of the polymer layer for laser processing is engraved by laser beams to provide a printing pattern. The flexographic printing plate may have a resin film which is laminated on the distant surface of the base layer of the laminated body for laser processing. The resin film is not particularly limited and polyester film is preferably used by taking pliancy and dimensional stability of the resin film into consideration. The thickness of the film is not specified and generally a film of 50 to 500 μm (more preferably 75 to 300 μm, still more preferably 100 to 200 μm) thick is used. In addition, the above described film can be generally laminated to the base layer using an adhesive or a binder. The tackifier or the adhesive layer can be laid on the surface of the resin film.

The method for fabricating the flexographic printing plate of the present invention comprises the following steps: carving the surface of the polymer layer of the laminated body for laser processing by means of laser beams and forming a printing pattern; and,

cutting the polymer layer for laser processing along the contour of the pattern; and,

peeling the regions of the polymer layer for laser processing wherein no printing pattern is formed from the base layer.

In the method described above a printing pattern with sufficient carving depth is obtained by fabricating the polymer layer for laser processing by means of laser beams and, moreover, emission of unpleasant odors can be restrained and stickiness of the worked surface almost eliminated. A carbon dioxide gas laser can be used primarily as a laser generating source. A laser power output for the fabrication of printing patterns is preferably 10 W or more, more preferably 50 W or more and still further preferably 100 W or more. The upper limit of the laser output is generally 3 kW. Further, since the polymer layer for laser processing can be peeled from the base layer the unnecessary portions where no printing pattern is present can be peeled from the base layer and removed. This will improve printing performance and workability during operation.

The sealing material of the present invention is characterized in that it is made of the polymeric material described above for laser processing. In the sealing material of the present invention another material can be laminated on the distant surface from the printing surface of this flexographic printing plate. As an additional material, a pliant material such as foamed polyurethane is preferable and this will enable a reduction in printing pressure.

### DESCRIPTION OF THE PREFFERED EMBODIMENTS

The features and advantages of the present invention have been set forth in further detail. In the expression of “parts” in the Examples and the Comparative Examples means “parts by mass” so far as no specific description is made.

1. Preparation and evaluation of the polymeric material for laser processing

### EXAMPLE 1

(1) Preparation of the admixture of polymer (A) with reinforcing agent and other additives.

Ethylene/propylene/non-conjugated diene rubber (hereinafter referred to as “EPDM”) (ethylene content: 61% by mass, JSR Corp., Trade Name: “JSR EP21”) as polymer (A) 100 parts, zinc oxide 5 parts, stearic acid 1 part, titanium oxide 5 parts, silica (Nippon Silica Industrial Co., Ltd., Trade Name: “Nipsil VN3”) 50 parts, calcium carbonate 50 parts and plasticizer (Idemitsu Kosan Co., Ltd., Trade Name: “Diana Process Oil PW380”) 60 parts were charged into a kneader with temperature controlled at 50° C. and kneaded for 15 minutes and an admixture was prepared.

(2) Preparation of the polymer composition and manufacture of the crosslinked sheet

The admixture prepared in the step (1) was charged into a roll of 4 inches in diameter and then organic peroxide (Kayaku AKZO Co., Ltd., Trade Name: “Perkadox14/40”) of 5 parts and 2 parts of triallyl isocyanurate as a crosslinkable monomer. After sufficient admixing the polymer composition was obtained. Then the polymer composition was charged into a mold of 2 mm in depth and compressed by a compression molder controlled at 170° C. for 25 minutes providing a crosslinked sheet.

(3) Evaluation of laser processing performance

The crosslinked sheet prepared in the step (2) was fabricated by a laser beam machine (Great Computer Corp., Trade Name: “Laser Pro”) with a hermetic carbon dioxide gas laser generator (Cinrad Co., U.S.A., output 25 W) and emission of odors, fuming and stickiness of the worked surface were evaluated (evaluation by touch) and carving depth was also measured. The laser beam machine was adjusted at a SPEED of 20%, and POWER of 100%, and resolution of 1000 dpi.

### EXAMPLE 2

In the step (2) of Example 1, except for 2 parts of azo di-carbonamide as a foaming agent and 2 parts of foaming aid (Sankyo Kasei Co., Ltd., Trade Name: “Cellton NP”) incorporated together with the organic peroxide and crosslinkable monomer, other ingredients and processes are the same as in Example 1. The crosslinked foamed sheet with a low degree of foam and an expansion ratio of 1.1 was obtained. Performance on laser processing of the crosslinked foamed sheet was evaluated in a similar manner as in Example 1.

### EXAMPLE 3

In the step (1) of Example 1 reinforcing agents (titanium oxide, silica and calcium carbonate) were replaced by 50 parts of carbon black (Tokai Carbon Co., Ltd., Trade Name: “Seast S”) and other ingredients and processes were unchanged. Then the crosslinked sheet was prepared in a similar manner as in the step (2) of Example 1 and performance in laser processing was evaluated in a similar manner as in Example 1.

### EXAMPLE 4

The admixture prepared in the preceding Example 3 was used and a crosslinked foamed sheet with a low degree of foaming and a expansion ratio of 1.1 was prepared. The performance on laser processing of this crosslinked foamed sheet was evaluated in a similar manner as in Example 1.

### EXAMPLE 5

In the step (1) of Example 1, 100 parts of EPDM and 25 parts of a nitrile rubber (in Table 1 referred to as NBR) (JSR Corp., Trade Name: “JSR N250S”) were used as the polymer (A). Except for the above, other ingredients were unchanged. Then in a similar manner as the step (2) of Example 1, the crosslinked sheet was prepared and performance in laser processing was evaluated as described in Example 1.

### EXAMPLE 6

The admixture prepared in Example 5 was used and a crosslinked foamed sheet with a low degree of foaming and a expansion ratio of 1.1 was prepared in a similar manner as in Example 2. Performance on laser processing of this crosslinked foamed sheet was evaluated in a similar manner as in Example 1.

### COMPARATIVE EXAMPLE 1

In the step (1) of Example 1, EPDM was replaced by 100 parts of the nitrile rubber (in Table 1 referred to as NBR) which was used in Example 5 and other ingredients and processes were unchanged and admixtures were prepared. Then crosslinked sheet was prepared in a similar manner as the step (2) of example 1. Performance on laser processing of this crosslinked sheet was evaluated in a similar manner as in Example 1.

### COMPARATIVE EXAMPLE 2

The admixture prepared in the step (1) of Example 1 was used, and in the step (2) of Example 1 the organic peroxide and crosslinkable monomer were replaced by 2 parts of sulfur, a vulcanizing agent, and 2 parts of a vulcanizing accelerator (Ouchishinko Chemical Industrial Co., Ltd., Trade Name “Nocceler CZ”)[in Table 1 referred to as a “vulcanizing accelerator (a)”] and 1 part of a vulcanizing accelerator (Trade Name: “Nocceler BZ”) [in Table 1 referred to as a “vulcanizing accelerator (b)”] and 1 part of a vulcanizing accelerator (Trade Name: “Nocceler TS”) [in Table 1 referred to as a “vulcanizing accelerator (c)”] were used. Other ingredients and processes were unchanged. A crosslinked sheet was prepared in a similar manner as in Example 1 and resulting crosslinked sheet was subjected to performance evaluation on laser processing in a similar manner as in Example 1.

### COMPARATIVE EXAMPLE 3

Ethylene/vinylacetate copolymer (content of ethylene unit: 40% by mass, Nippon Synthetic Chemical Industry Co., Ltd., Trade Name: “Sourblen CH”) (in Table 1 referred to as EVA) was used as a sole ingredient and a sheet was prepared by compression for 5 minutes at a controlled temperature of 100° C. utilizing a compression molding machine. The sheet was subjected to performance evaluation for laser processing in a similar manner as in Example 1.

The results of performance evaluation for laser processing in Example 1 to 6 and Comparative Example 1 to 3 are shown in Table 1.

According to the results in Table 1 it is understood that the crosslinked sheet or crosslinked foamed sheet of Example 1 to 6 did not emit unpleasant odors and no fuming was observed during the process of laser processing. Further, stickiness on the working surface was not present providing a pattern with sufficient carving depth. On the other hand, in the Comparative Example 1 wherein NBR was used, and in Comparative Example 2 wherein EPDM was vulcanized by sulfur, both suffered from emission of unpleasant odors generated by burning rubber during the laser processing process. Further, Comparative Example 3, wherein EVA having a content of an ethylene unit of less than 45% by mass as a single ingredient emission of unpleasant acid-like odors was generated.

TABLE 1

| | |
|---|---|
| Example | Comparative |

| | 1 | 2 | 3 | 4 | 5 | 6 | 1 | 2 | 3 |
|---|---|---|---|---|---|---|---|---|---|
| EPDM | 100 | 100 | 100 | 100 | 100 | 100 | — | 100 | — |
| NBR | — | — | — | — | 25 | 25 | 100 | — | — |
| EVA | — | — | — | — | — | — | — | — | 100 |
| Zinc oxide | 5 | 5 | 5 | 5 | 5 | 5 | 5 | 5 | — |
| Stearic acid | 1 | 1 | 1 | 1 | 1 | 1 | 1 | 1 | — |
| Titanium oxide | 5 | 5 | — | — | 5 | 5 | 5 | 5 | — |
| Silica | 50 | 50 | — | — | 50 | 50 | 50 | 50 | — |
| Calcium carbonate | 50 | 50 | — | — | 50 | 50 | 50 | 50 | — |
| Carbon black | — | — | 50 | 50 | — | — | — | — | — |
| Plasticizer | 60 | 60 | 60 | 60 | 60 | 60 | 60 | 60 | — |
| Organic peroxide | 5 | 5 | 5 | 5 | 5 | 5 | 5 | — | — |
| Crosslinkable monomer | 2 | 2 | 2 | 2 | 2 | 2 | 2 | — | — |
| Sulfur | — | — | — | — | — | — | — | 2 | — |
| Vulcanization accelerator | | | | | | | | | |
| (a) | — | — | — | — | — | — | — | 2 | — |
| (b) | — | — | — | — | — | — | — | 1 | — |
| (c) | — | — | — | — | — | — | — | 1 | — |
| Foaming agent | — | 2 | — | 2 | — | 2 | — | — | — |
| Foaming aid | — | 2 | — | 2 | — | 2 | — | — | — |
| Laser | | | | | | | | | |
| fabrication | | | | | | | | | |
| Fuming | ∘ | ∘ | ∘ | ∘ | ∘ | ∘ | ∘ | ∘ | ∘ |
| Surface stickiness | ∘ | ∘ | ∘ | ∘ | ∘ | ∘ | ∘ | ∘ | ∘ |
| Odor | ∘ | ∘ | ∘ | ∘ | ∘ | ∘ | X | X | X |
| Carving depth (mm) | 1.0 | 1.5 | 1.0 | 1.5 | 1.0 | 1.5 | 1.0 | 1.0 | 1.3 |

2. Preparation of polymer layer for laser processing and evaluation

### EXAMPLE 7

(1) Preparation of polymer layer for laser processing

As ethylenic copolymer EPDM described above was used. EPDM 100 parts, zinc oxide 5 parts, stearic acid 1 part, titanium oxide 5 parts, abovementioned silica 50 parts, calcium carbonate 50 parts and plasticizer X(Idemitsu Kosan Co., Ltd., Trade Name: “Diana Process Oil PW380”) 60 parts were charged into a kneader controlled at 50° C. and were admixed for 15 minutes and an admixture was prepared.

The prepared admixture was charged into a roll with 4 inches in diameter and maintained at 50° C., and thereafter 5 parts of the organic peroxide described above, and 2 parts of triallyl isocyanurate which is a crosslinked monomer was further charged. After sufficient blending the polymer composition was charged into a mold of 3 mm in depth and compressed by means of a compression molding machine with temperature controlled at 170° C. and the polymer layer for laser processing was prepared.

(2) Preparation of photopolymerizable composition

A isoprene/butadiene/isoprene block copolymer (JSR Corp., Trade Name: “JSR SIS5000”) was used as the elastomer component. 100 parts of this elastomer, 10 parts of 1,6-hexanediol-dimethacrylate, 10 parts of laurylmethacrylate, 2 parts of 2,2-dimethoxy-1,2-diphenylethane-1-on as a photoinitiator, and 1 part of 2,6-di-t-butylcresol as a thermal polymerization inhabiter were charged in a kneader controlled at 50° C. and kneaded for 30 minutes. And a colorless, transparent photopolymerizable composition was obtained.

(3) Preparation of laminated body sheet

After slightly polishing one of the surfaces of the sheet of 3 mm in thickness which had been prepared in the step (1) by sandpaper (#200), the sheet was placed within a mold of 7 mm in depth and the photopolymerizable composition prepared in the preceding process (2) was laid on the polished surface of the sheet. Then a polyester film (200 μm in thickness) was overlaid on the surface of the composition. These materials were molded by a press controlled at 90° C. and a pliant laminated body of 7 mm in thickness was obtained. The laminated body was exposed to ultraviolet rays from the exposure device (Nippon Denshi Seiki Co., Ltd., Type JE-A3-SS) on the surface of the photopolymerizable composition side for 5 minutes (intensity of ultraviolet rays 25 W/m²) and the laminated body for laser processing was obtained. The peel strength of the laminated body was measured according to the method specified by JIS K 6301 and separation was evaluated when peeled manually. The results of the measurement and evaluation of the manual test are summarized in Table 2. Now, the testing procedures for peel strength will be explained briefly. A square piece (2.5 cm wide×15 cm long) was taken from the laminated body and one end portion of the piece was peeled manually to provide a test sample. The peeled end portions of both layers were attached to the testing machine, respectively, making about a 180° separation toward the reverse direction and peel strength was measured at a tensile rate of 5 cm/min.

(4) Evaluation of performances on laser processing

The laminated body for laser processing prepared in the step (3) was subjected to laser processing by the laser working machine used in the step (3) of Example 1. Results of the evaluation concerning fuming, stickiness of the working surface and emission of unpleasant odors and results of the measurement of carving depth are shown in Table 2. In Table 2, code “O” refers to “good” or “absence”, and code “X” refers to “worse” or “large”.

### EXAMPLE 8

In the step (1) of Example 7, the organic peroxide and crosslinkable monomer and additionally 2 parts of azo-dicarbonamide as a foaming agent and also 2 parts of foaming aid (Sankyo Kasei Co., Ltd., Trade Name: “Cellton NP”) were charged and other ingredients and processes were unchanged. A crosslinked foamed sheet material with an expansion ratio of 1.1 was prepared in a similar manner as in Example 7. A laminated body for laser processing was made in a similar manner as in the preceding Example 7 and separation and performance in laser processing were evaluated.

### EXAMPLE 9

(1) Preparation of polymer layer for laser processing

As an ethylenic copolymer, EPDM described above was used. 100 parts of EPDM, 5 parts of zinc oxide, 1 part of stearic acid, and 5 parts of titanium oxide, 50 parts of silica, 50 parts of calcium carbonate and 60 parts of plasticizer Y (Mitsui Chemical Co., Ltd., Trade Name: “LUCANT HC-150”) were charged into a kneader controlled at 50° C. and blended by mixing for 15 minutes resulting in an admixture for the polymer layer of the laminated body for laser processing. The polymer layer for laser processing was fabricated in a similar manner as in Example 7 and results of the evaluation are shown in Table 2.

TABLE 2

| | | Example | | |
|---|---|---|---|---|
| | | 7 | 8 | 9 |
| Formulation of polymer | | | | |
| layer for laser processing | | | | |
| EPDM | | 100 | 100 | 100 |
| Zinc oxide | | 5 | 5 | 5 |
| Stearic acid | | 1 | 1 | 1 |
| Titanium oxide | | 5 | 5 | 5 |
| Silica | | 20 | 20 | 20 |
| Calcium carbonate | | 50 | 50 | 50 |
| Plasticizer X | | 60 | 60 | — |
| Plasticizer Y | | — | — | 60 |
| Organic peroxide | | 5 | 5 | 5 |
| Crosslinkable monomer | | 2 | 2 | 2 |
| Foaming agent | | — | 2 | — |
| Foaming aid | | — | 2 | — |
| Formulation of base layer | | | | |
| Isoprene/butadiene/isoprene block copolymer | | 100 | 100 | 100 |
| 1,6-Hexanediol dimethacrylate | | 10 | 10 | 10 |
| Lauryl methacrylate | | 10 | 10 | 10 |
| 2,2-dimethoxy-1,2-diphenylmethane | | 2 | 2 | 2 |
| 2,6-di-t-butylcresol | | 1 | 1 | 1 |
| Method of lamination | | Press | Press | Extrude |
| Peel strength (N/cm) | | 7.84 | 6.86 | 6.86 |
| Peeling workability | | ◯ | ◯ | ◯ |
| Laser | Fuming | ◯ | ◯ | ◯ |
| fabrication | Surface stickiness | ◯ | ◯ | ◯ |
| | Odor | ◯ | ◯ | ◯ |
| | Carving depth (mm) | 1.0 | 1.5 | 1.0 |

(2) Preparation of photopolymerizable composition

The composition was prepared in a similar manner as in

### EXAMPLE 7

(3) Preparation of laminated body sheet

The photopolymerizable composition prepared in the step (3) of Example 7 was charged into a single screw extruder with T-die, which had been controlled at 80° C. At the exit of the die, molten composition was laminated on the surface of the polished surface which had been formed in the step (3) of Example 7. As a support, polyester film (200 μm in thickness) having a coated layer of a chloroprene-based adhesive (Hitachi Chemical Co., Ltd., Trade Name: “HIBON 1920LT”) with 5 μm in thickness was adhered to the surface of the side of a photopolymerizable layer after the lamination was completed. Then the thickness of the laminated body was adjusted by means of thickness adjustment rolls having a 7 mm clearance between rolls. The laminated body obtained showed excellent precision in thickness and was exposed to ultraviolet rays from the photopolymerizable layer side for 5 minutes (intensity of ultraviolet rays: 25 W/m²) utilizing a light filter (Nippon Denshi Seiki K.K., Type JE-A3-SS) whereby a laminated body for laser processing was obtained. The laminated body for laser processing was then subjected to evaluation of performances on peeling and laser processing in a similar manner as in Example 7. The results of the evaluation are shown in Table 2.

According to the results of Table 2 it is understood that the laminated body for laser processing is capable of being peeled between the surfaces of the polymer layer for laser processing and the base layer in all Examples 7 to 9. Further sufficient carving depth is obtained by laser processing without flaming and emission of unpleasant odors during operation.

A flexographic printing plate can be made by carving a printing pattern on the surface of the laminated body for laser processing with such excellent properties as shown in the Examples. The flexographic printing plate according to the present invention has a laminated structure with flexibility and consequently, the following effects are expected due to excellent printing performance and workability.

(1) The flexographic printing plate can be easily attached to a rotating machine such as a rotary press and will reduce printing pressure on the object to be printed.

(2) Laser engraving is carried out only on regions where the character patterns exist since the unengraved region can be peeled later, and processing time can be considerably reduced.

(3) The printing plate is light in weight, since other portions than patterns have been already removed.

(4) As the photopolymerizable layer lies under the printing surface and transparency of the base layer has increased, the printing plate is readily attached (located) to a rotary press.

The above features are especially advantageous when a printing plate is relatively large in size in order to be used for printing corrugated board or the like.

What is claimed is:

1. A polymeric material for laser processing being characterized in that a polymer composition comprising a polymer (A) containing 45% or more by mass of an ethylene unit as a repeating unit and an organic peroxide (B) is crosslinked.

2. A polymeric material for laser processing being characterized in that a polymer composition comprising a polymer (A) containing 45% or more by mass of an ethylene unit as a repeating unit and an organic peroxide (B) and a foaming agent (C) is crosslinked and foamed.

3. A laminated body for laser processing comprising a polymer layer for laser processing obtained by crosslinking a polymer composition containing an ethylenic copolymer and a base layer laminated to one side of a surface of said polymer layer for laser processing, wherein both layers are capable of being peeled from each other at the interface.

4. The laminated body for laser processing according to claim 3, wherein the peel strength is in the range of 2 to 40 N/cm when said polymer layer is peeled from said base layer at the interface with a peeling rate of 5 cm/min at 180 degrees.

5. The laminated body for laser processing according to claim 4, wherein said polymer composition comprises a polymer (A) containing 45% or more by mass of an ethylene unit as a repeating unit and an organic peroxide (B).

6. The laminated body for laser processing according to claim 5, wherein said base layer is formed using a photopolymerizable composition, wherein a photopolymerizable composition comprising an elastomer and a compound having an ethylenical unsaturated group and a photoinitiator is photocured.

7. A method for producing a laminated body for laser processing comprising:
a step for forming a polymer sheet by crosslinking a polymerizable composition containing an ethylenic copolymer;
a step for laminating a photopolymerizable layer containing an elastomer and a compound having an ethylenical unsaturated group and a photocuring initiator to the surface of the polymer sheet; and
a step for irradiating ultraviolet ray to one side of said photopolymerizable layer and photocuring said photopolymerizable layer to form a base sheet.

8. A flexographic printing plate being characterized in that made of a polymeric material for laser processing that a polymer composition comprising a polymer (A) containing 45% or more by mass of an ethylene unit as a repeating unit and an organic peroxide (B) is crosslinked.

9. A flexographic printing plate being characterized in that made of a polymeric material for laser processing that a polymer composition comprising a polymer (A) containing 45% or more by mass of an ethylene unit as a repeating unit and an organic peroxide (B) and a foaming agent (C) is crosslinked and foamed.

10. A flexographic printing plate characterized in that a printing pattern is formed by engraving the surface of said polymer layer for laser processing in the laminated body for laser processing comprising a polymer layer for laser processing obtained by crosslinking a polymer composition containing an ethylenic copolymer and a base layer laminated to one side of a surface of said polymer layer for laser processing, wherein both layers are capable of being peeled from each other at the interface, with laser processing.

11. A flexographic printing plate according to claim 10, wherein the peel strength is in the range of 2 to 40 N/cm when said polymer layer is peeled from said base layer at the interface with a peeling rate of 5 cm/min at 180 degrees.

12. A flexographic printing plate according to claim 10, wherein a film of polymer resin is laminated on the other surface of said base layer of said laminated body for laser processing.

13. A method for producing a flexographic printing plate comprising:
a step for making a printing pattern by engraving the surface of said polymer layer for laser processing in said laminated body for laser processing comprising a polymer layer for laser processing obtained by crosslinking a polymer composition containing an ethylenic copolymer and a base layer laminated to one side of a surface of said polymer layer for laser processing, wherein both layers are capable of being peeled from each other at the interface;
a step for cutting said polymer layer for laser processing along said printing pattern; and
a step for peeling a region which said printing pattern of said polymer layer for laser processing has not been formed from said base layer.

14. A material for a seal characterized in that is made of a polymeric material for laser processing that a polymer composition comprising a polymer (A) containing 45% or more by mass of an ethylene unit as a repeating unit and an organic peroxide (B) is crosslinked.

15. A material for a seal characterized in that is made of a polymeric material for laser processing that a polymer composition comprising a polymer (A) containing 45% or more by mass of an ethylene unit as a repeating unit and an organic peroxide (B) and a foaming agent (C) are crosslinked and foamed.
